(19) United States
(12) Patent Application Publication
(10) Pub. No.: US 2017/0047271 A1
(43) Pub. Date: Feb. 16, 2017

(54) METHOD FOR MAKING A SEMICONDUCTOR DEVICE HAVING AN INTERPOSER

(71) Applicant: FREESCALE SEMICONDUCTOR, INC., AUSTIN, TX (US)

(72) Inventor: MATTHEW J. ZAPICO, CEDAR PARK, TX (US)

(21) Appl. No.: 14/821,974

(22) Filed: Aug. 10, 2015

(51) Int. Cl. H01L 23/495; H01L 21/56; H01L 23/31; H01L 21/48

(52) U.S. Cl. CPC H01L 23/49513; H01L 21/4825; H01L 21/4828; H01L 21/565; H01L 23/4952; H01L 23/49541; H01L 23/49582; H01L 23/3114

(57) ABSTRACT

A semiconductor device and a method for making the semiconductor device are provided. The semiconductor device comprises a leadframe and a metal interposer. The leadframe has a plurality of leads and a flag. The metal interposer is attached to the flag. A semiconductor die is attached to the metal interposer. A plurality of wirebonds is connected between the metal interposer and the leadframe. A plurality of wirebonds is connected between the semiconductor die and the metal interposer. An encapsulant is formed over the die, the metal interposer, and a portion of the leadframe. Using the metal interposer in the manner allows relatively inexpensive and quick wiring changes to the leadframe.

### BACKGROUND

Field

This disclosure relates generally to semiconductor device packaging, and more specifically, to packaging a semiconductor device including an interposer.

Related Art

Today, many semiconductor devices are packaged in low cost packaging which generally includes a semiconductor die attached to a leadframe and encapsulated in a plastic encapsulant. As production quantities of the semiconductor devices increase, cost savings can be further realized by using high volume stamped leadframes in the packaging process. Stamped leadframes are generally formed by stamping a tooled pattern onto a sheet of metal, such that features of the leadframes are separated from unused portions of the sheet. Because stamped leadframes are typically run in high volume production, costs are low and lead times are short. The tooling alone for stamped leadframes, however, can be very expensive and may require very long lead times.

Etched leadframes are generally used in packaging new semiconductor devices when open tooled or existing high volume stamped leadframes may not be compatible. Etched leadframes are typically formed by chemically etching a photoresist patterned sheet of metal such that the unused portions of the sheet are removed from features of the leadframes. Because etched leadframes are typically more expensive than stamped leadframes, etched leadframes can be more suitable for lower volume production run rates.

With the rate at which new semiconductor devices are being developed, a more cost and time sensitive approach is desired in packaging these new semiconductor devices.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a plan view of an exemplary leadframe according to an embodiment of the present disclosure.

FIG. 2 is a plan view of an exemplary interposer according to an embodiment of the present disclosure.

FIG. 3 is a plan view of an exemplary semiconductor die according to an embodiment of the present disclosure.

FIGS. 4-6 are simplified cross-sectional views of an exemplary semiconductor device during various stages manufacture according to an embodiment of the present disclosure.

### DETAILED DESCRIPTION

The present disclosure describes a lower cost and shorter lead time packaging for a semiconductor device. The semiconductor device packaging includes a lead frame having a flag and a plurality of leads surrounding the flag, and a metal interposer having a die attach flag and a plurality of wirebond leads, wherein a semiconductor die is mounted to the die attach flag of the interposer and the interposer is mounted to the leadframe. By using an open tooled or stamped leadframe in combination with a custom etched metal interposer, expensive stamped tooling with very long lead times can be bypassed.

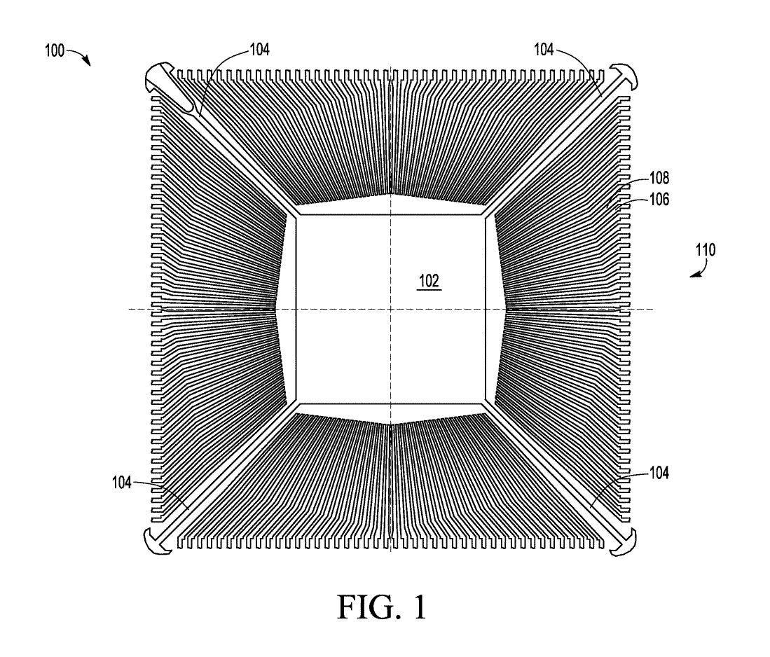

FIG. 1 is a plan view of an exemplary semiconductor device package leadframe according to an embodiment of the present disclosure. Leadframe 100 includes a flag 102, a plurality of tie bars 104, and a plurality of leads 110 surrounding the flag 102. Leadframe 100 may be formed of any suitable electrically conductive material that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like. In some embodiments, the flag 102 may be formed of a material different from the plurality of leads 110 surrounding the flag 102. In some embodiments, the flag 102 may be plated with a material different from the plurality of leads. In some embodiments, the flag 102 may be bare and the plurality of leads 110 may be plated, or the flag 102 may be plated and the plurality of leads 110 may be bare. Leadframe 100 is a stamped leadframe, suitable for high volume production run rates. In some embodiments, leadframe 100 may be an etched leadframe.

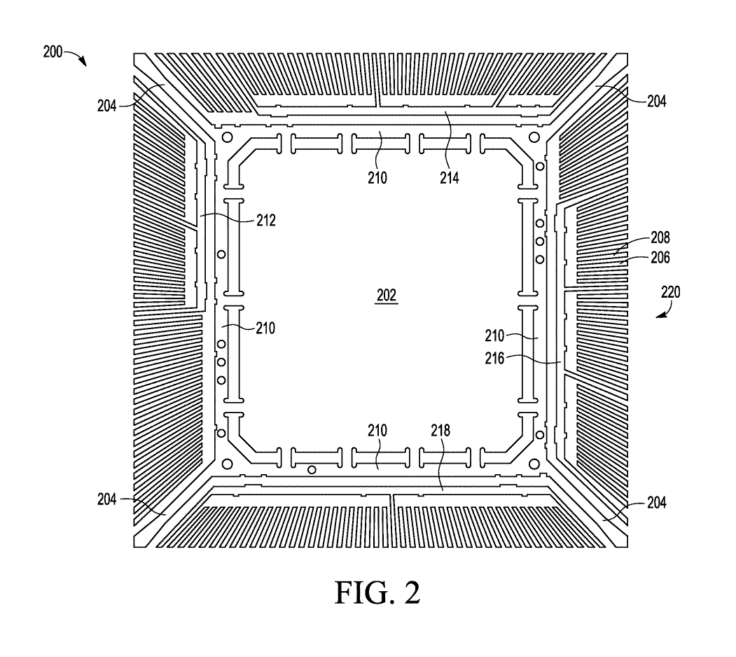

Still referring to FIG. 1, flag 102 is supported by four tie bars 104. The flag 102 includes an attach area for attaching an interposer (see FIG. 2). The flag 102 may be any shape, size, or configuration suitable for an attached interposer. In some embodiments, the flag 102 may be characterized as a downset flag where the plane of the flag 102 is below the plane of the plurality of leads 110. In some embodiments, because the plurality of tie bars 104 are connected to the flag 102, one or more of the tie bars can be wirebonded to form electrical connections to the flag 102, for example, when it is desirable for the flag 102 to be grounded. The flag 102 is surrounded by the plurality of leads 110. Individual leads, such as leads 106 and 108 of the plurality of leads 110, are generally finger shaped and extend radially from the flag 102 to a perimeter of the semiconductor device package. The plurality of leads 110 provide electrical connectivity between wirebond sites near the flag 102 and external electrical connection locations of the semiconductor device package.

FIG. 2 is a plan view of an exemplary metal interposer according to an embodiment of the present disclosure. Interposer 200 includes a die attach flag 202, a plurality of interposer tie bars 204, a plurality of wirebond leads 220 surrounding the die attach flag 202, a ground ring 210, and bus bars 212-218. Interposer 200 may be formed of any suitable electrically conductive material that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like. In some embodiments, the die attach flag 202 may be formed of a material different from the plurality of wirebond leads 220 surrounding the die attach flag 202. In some embodiments, the die attach flag 202 may be plated with a material different from the plurality of wirebond leads 220. In some embodiments, the die attach flag 202 may be bare and the plurality of wirebond leads 220 may be plated, or the die attach flag 202 may be plated and the plurality of wirebond leads 220 may be bare. Interposer 200 is an etched metal interposer. In some embodiments, interposer 200 may be a stamped metal interposer.

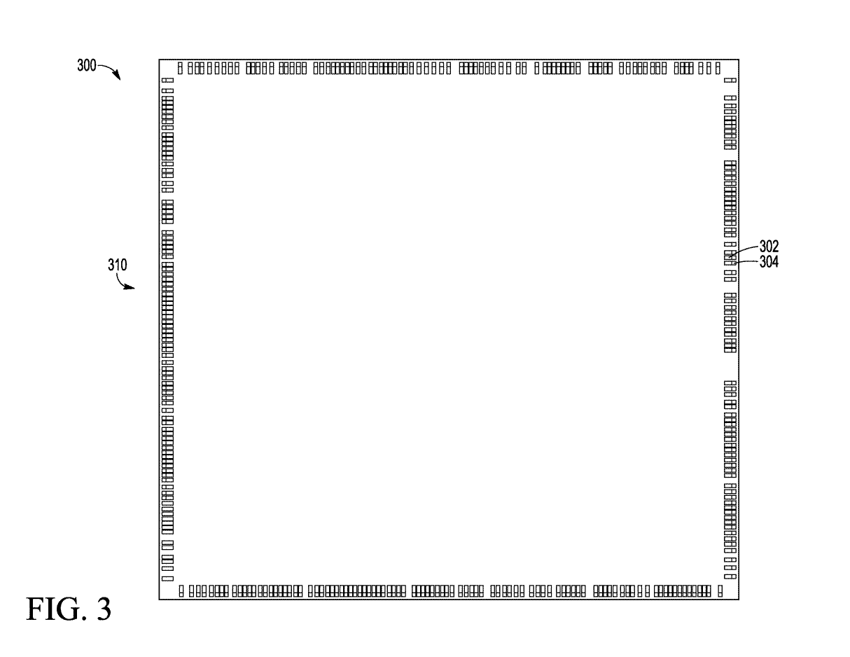

The die attach flag 202 is supported by the plurality of interposer tie bars 204. The die attach flag 202 includes a die attach area for attaching a semiconductor die (see FIG. 3). The die attach flag 202 may be any shape, size, or configuration suitable for an attached semiconductor die. The plurality of interposer tie bars 204 provide support for the die attach flag 202 as well as electrical connectivity to the die attach flag 202. For example, one or more of the interposer tie bars can be wirebonded to a ground supply terminal when it is desirable for the die attach flag 202 to be grounded. The die attach flag 202 is surrounded by the plurality of wirebond leads 220. Individual wirebond leads, such as wirebond leads 206 and 208, are generally finger shaped and extend radially from the die attach flag 202 to an outer perimeter of the interposer 200. The plurality of wirebond leads 220 forms an intermediate wire routing arrangement including wirebond sites to couple electrical signals between locations on the semiconductor die attached to the interposer and the plurality leads 110 near the flag 102 of the leadframe.

The ground ring 210 is formed around the perimeter of the die attach flag 202. A series of slots or openings formed in the metal of the die attach flag 202 isolate the ground ring 210 from the die attach area of the die attach flag 202. Locations on the semiconductor die such as ground pads can be wirebonded to the ground ring 210 rather than to individual wirebond leads, reducing the overall number of wirebond leads needed for the ground supply, for example. Bus bars 212-218 are formed at the plurality of wirebond leads 220 end near the perimeter of the die attach flag 202 and ground ring 210. Bus bars 212-218 provide broad wirebond sites for power supply connectivity. For example, multiple locations on the semiconductor die such as power pads can be wirebonded to bus bar 212 rather than to individual wirebond leads, reducing the overall number of wirebond leads needed for the power supply connectivity corresponding to bus bar 212. By reducing the overall number of wirebond leads used for power and ground supply connectivity, more wirebond leads in the plurality of wirebond leads 220 can be available to couple electrical signals between locations on the semiconductor die and the leadframe plurality of leads 110. Thus, the interposer 200, including ground ring 210 and bus bars 212-218, enables a high pin count semiconductor die to be wirebonded to a lower pin count leadframe.

FIG. 3 is a plan view of an exemplary semiconductor die according to an embodiment of the present disclosure. Semiconductor die 300 includes a plurality of bond pads 310 located around the perimeter of the die. Semiconductor die 300 may be formed of any semiconductive material, such as a silicon, germanium, gallium arsenide, and the like. Semiconductor die 300 may include circuitry such as digital circuits, analog circuits, a processor, a memory, and the like. Semiconductor die 300 may include sensors such as a motion sensor, temperature sensor, light sensor, image sensor, and the like. Individual bond pads, such as bond pads 302 and 304, are generally square or rectangular shaped and distributed radially around an outer perimeter of the semiconductor die 300. Wirebonds electrically couple signals between the plurality of bond pads 310 and the plurality of wirebond leads 220 of the interposer 200.

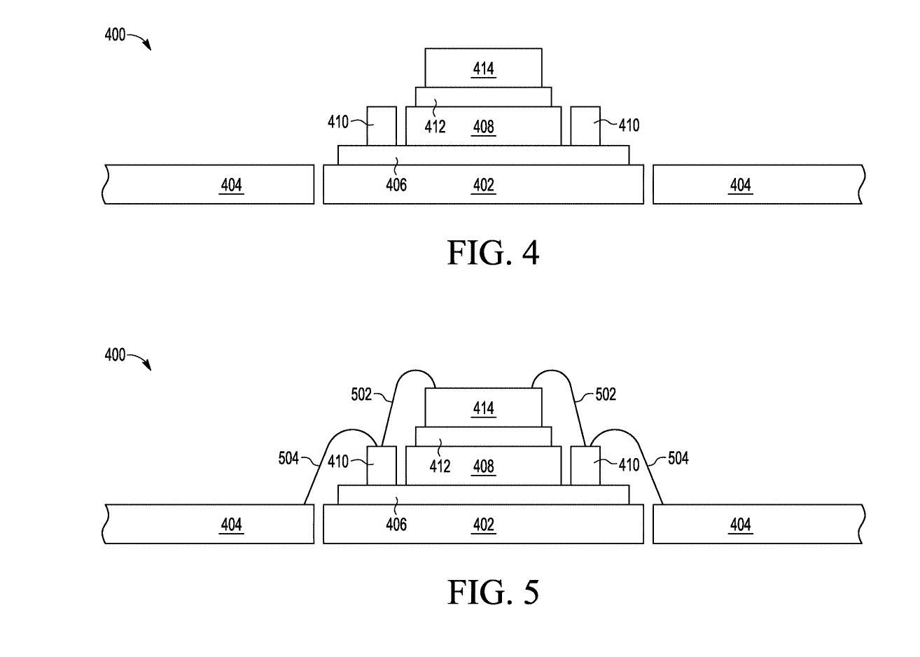

FIGS. 4-6 are simplified cross-sectional views of an exemplary semiconductor device during various stages manufacture according to an embodiment of the present disclosure.

FIG. 4 illustrates in cross-sectional view form, a stage of manufacture of an exemplary semiconductor device 400 including leadframe, a metal interposer, and a semiconductor die. The leadframe, such as leadframe 100 in FIG. 1 discussed above, includes a flag 402 suitable for attachment of an interposer and plurality of leads 404. The leadframe may be formed of any suitable electrically conductive material that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like. The leadframe in this example is a stamped leadframe, suitable for high volume production run rates. In some embodiments, the leadframe may be an etched leadframe.

The flag 402 is typically supported by one or more tie bars (not shown) and includes an attach area for attaching an interposer. The flag 402 may be any shape, size, or configuration suitable for an attached interposer. In some embodiments, the flag 402 may be characterized as a downset flag where the plane of the flag 402 is below the plane of the plurality of leads 404. The plurality of leads 404 couple electrical signals between locations at the outside of a finished semiconductor device package and locations within the package such as wirebond sites on the leads near the flag 402.

The metal interposer, such as interposer 200 in FIG. 2 discussed above, is attached to the attach area of the flag 402 with an adhesive 406. The adhesive 406 may be a solder alloy, an epoxy, or any suitable die-attach material such as a non-conductive die-attach film. The interposer includes a die attach flag 408, and a plurality of wirebond leads 410 surrounding the die attach flag 408. The interposer may be formed of any suitable electrically conductive metal that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like. The metal interposer has substantially the same coefficient of thermal expansion as the leadframe. The plurality of wirebond leads 410 forms intermediate wire routing arrangement including wirebond sites to couple electrical signals between locations on the semiconductor die 414 and wirebond sites on the leads 404 near the flag 402.

The semiconductor die 414, such as semiconductor die 300 in FIG. 3 discussed above, is attached to the interposer flag 408 with an adhesive 412. The adhesive 412 may be a solder alloy, an epoxy, or any suitable die-attach material such as a die-attach film, for example. The semiconductor die 414 includes a plurality of bond pads located around the perimeter of the die. Semiconductor die 414 may be formed of any semiconductive material, such as a silicon, germanium, gallium arsenide, and the like. Semiconductor die 414 may include any or combination of digital circuits, analog circuits, memory, processor, MEMS, sensors, and the like.

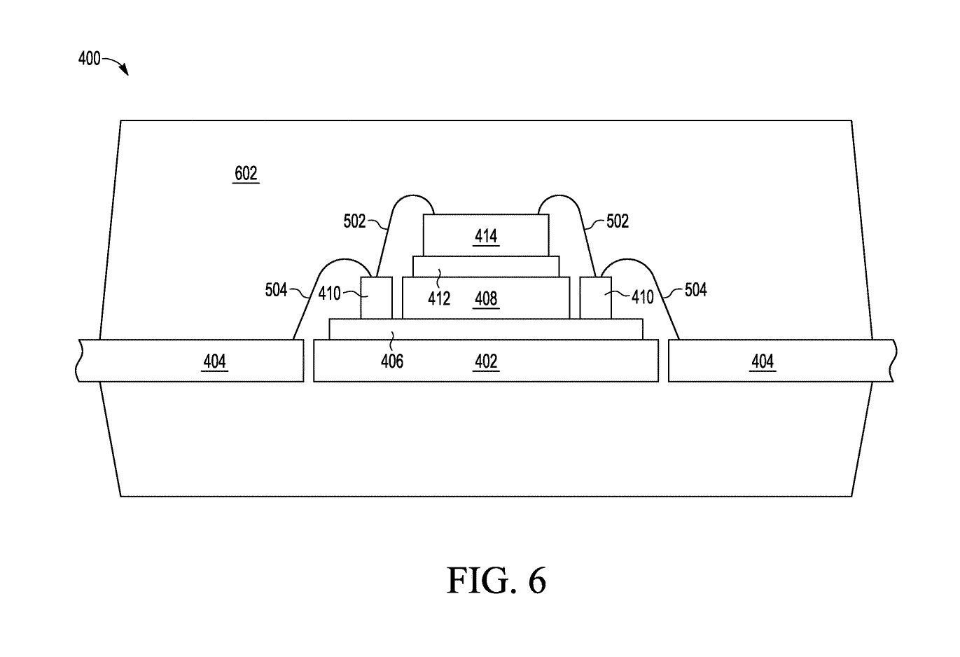

FIG. 5 illustrates in cross-sectional view form, a subsequent stage of manufacture of the exemplary semiconductor device 400 depicted in FIG. 4. A first plurality of bond wires 502 and a second plurality of bond wires 504 are shown. The first and second pluralities of bond wires may be formed of a metal comprising aluminum, copper, silver, or gold. The first plurality of bond wires may be formed of a different metal than those of the second plurality of bond wires. Bond wires 502 electrically couple a plurality of locations on the semiconductor die 414 to the plurality of wirebond leads 410 of the interposer. Similarly, bond wires 504 electrically couple the plurality of wirebond leads 410 to the plurality of leads 404 of the leadframe. Bond wires 502 and 504 may be attached to the semiconductor die 414, the interposer wirebond leads 410, and the leadframe leads 404 with either ball bonds or wedge bonds or a combination of ball bonds and wedge bonds. For example, ball bonds may be used to attach a first end of bond wires 502 to bond pads of the semiconductor die 414 while wedge bonds may be used to attach the opposite ends of bond wires 502 to the wirebond leads 410 of the interposer.

FIG. 6 illustrates in cross-sectional view form, a subsequent stage of manufacture of the exemplary semiconductor device 400 depicted in FIG. 5. A mold compound 602 encapsulates the semiconductor die 414, bond wires 502 and 504, interposer die attach flag 408 and wirebond leads 410, leadframe flag 402, and a portion of leadframe leads 404 to form a semiconductor device package. The semiconductor device package may be in the form of a quad flat pack (QFP) package, small outline integrated circuit (SOIC) package, quad flat no-lead (QFN) package, or the like. The encapsulant 602 may be any suitable mold compound such as a plastic mold compound or an epoxy mold compound. The encapsulating process may include any suitable molding technique such as injection molding for example.

By now it should be appreciated that there has been provided a lower cost and shorter lead time packaging for a semiconductor device. The semiconductor device packaging includes a lead frame having a flag and a plurality of leads surrounding the flag, and a metal interposer having a die attach flag and a plurality of wirebond leads, wherein a semiconductor die is mounted to the die attach flag of the interposer and the interposer is mounted to the leadframe. By using an open tooled or stamped leadframe in combination with a custom etched metal interposer, expensive stamped tooling with very long lead times can be bypassed.

Generally, there is provided, a method for making a semiconductor device, the method including: providing a leadframe having a plurality of leads and a flag; attaching a metal interposer to the flag; attaching a semiconductor die to the metal interposer; providing wirebonds between the metal interposer and the leadframe; providing wirebonds between the semiconductor die and the metal interposer; and encapsulating the semiconductor die, metal interposer, and a portion of the leadframe. The metal interposer may be used to provide a wire routing arrangement between the semiconductor die and the leadframe. The method may further include etching the metal interposer to provide the wire routing arrangement. The metal interposer and the leadframe may each be formed from a metal comprising copper. Attaching a metal interposer to the flag may further include attaching the metal interposer to the flag using a non-conductive die attach film. Attaching a semiconductor die to the metal interposer may further include attaching the semiconductor die to the metal interposer using a die attach material. Encapsulating the semiconductor die, metal interposer, and a portion of the leadframe may further include encapsulating with an epoxy mold compound. The semiconductor device may be characterized as being one of a quad flat pack (QFP) package, small outline integrated circuit (SOIC) package, or quad flat no-lead (QFN) package. The metal interposer may have substantially the same coefficient of thermal expansion as the leadframe.

In another embodiment, there is provided, a semiconductor device including: a leadframe having a plurality of leads and a flag; a metal interposer attached to the flag; a semiconductor die attached to the metal interposer; a plurality of wirebonds connected between the metal interposer and the leadframe; a plurality of wirebonds connected between the semiconductor die and the metal interposer; and an encapsulant formed over the die, the metal interposer, and a portion of the leadframe. The metal interposer may include a bus bar by which the plurality of wirebonds connected between the semiconductor die and the metal interposer may be connected to the bus bar, and a single wire bond may be connected between the bus bar and one lead of the plurality of leads of the leadframe. The bus bar may be used for routing a power supply voltage to the semiconductor device. The metal interposer may include a bus bar for enabling a high pin count semiconductor die to be wirebonded to a lower pin count leadframe. Both pluralities of wirebonds may be formed using a wire comprising copper. The leadframe and the metal interposer may both be formed from a metal sheet comprising copper, and the metal interposer may be etched to provide electrical conductors between the semiconductor die and the leadframe.

In yet another embodiment, there is provided, a semiconductor device including: a leadframe having a plurality of leads and a flag; an interposer attached to the flag, the interposer formed from a same material as the leadframe; a semiconductor die attached to the interposer; a plurality of wirebonds connected between the interposer and the leadframe; a plurality of wirebonds connected between the semiconductor die and the interposer; and an encapsulant formed over the die, the interposer, and a portion of the leadframe. The leadframe and the interposer may both be formed from a metal comprising copper. The interposer may include a bus bar for enabling a high pin count semiconductor die to be wirebonded to a lower pin count leadframe. The semiconductor device may be characterized as being one of a quad flat pack (QFP) package, small outline integrated circuit (SOIC) package, or quad flat no-lead (QFN) package. The interposer may be attached to the flag with a non-conductive die attach film.

The semiconductor die described herein can be formed from any semiconductor material or combinations of materials, such as gallium arsenide, silicon germanium, silicon-on-insulator (SOI), silicon, monocrystalline silicon, the like, and combinations of the above.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method for making a semiconductor device, the method comprising:
providing a leadframe having a plurality of leads and a flag;
attaching a metal interposer to the flag, the metal interposer having a plurality of wirebond leads and a die attach flag formed from a same metal as the wirebond leads;
attaching a semiconductor die to the die attach flag of the metal interposer;
providing wirebonds between the wirebond leads of the metal interposer and the leadframe;
providing wirebonds between the semiconductor die and the wirebond leads of the metal interposer; and
encapsulating the semiconductor die, metal interposer, and a portion of the leadframe.

2. The method of claim 1, wherein the wirebond leads of the metal interposer form a wire routing arrangement between the semiconductor die and the leadframe.

3. The method of claim 2, wherein the metal interposer further comprises a plurality of tie bars supporting the die attach flag, the tie bars included in the wire routing arrangement and providing electrical connectivity to the die attach flag.

4. The method of claim 1, wherein the metal interposer and the leadframe are each formed from a metal comprising copper.

5. The method of claim 1, wherein attaching a metal interposer to the flag further comprises attaching the metal interposer to the flag using a non-conductive die attach film.

6. The method of claim 1, wherein attaching a semiconductor die to the die attach flag of the metal interposer further comprises attaching the semiconductor die to the die attach flag of the metal interposer using a die attach material.

7. The method of claim 1, wherein encapsulating the semiconductor die, metal interposer, and a portion of the leadframe further comprises encapsulating with an epoxy mold compound.

8. The method of claim 1, wherein the semiconductor device is characterized as being one of a quad flat pack (QFP) package, small outline integrated circuit (SOIC) package, or quad flat no-lead (QFN) package.

9. The method of claim 1, wherein the metal interposer has substantially the same coefficient of thermal expansion as the leadframe.

10. A semiconductor device comprising:
a leadframe having a plurality of leads and a flag;
a metal interposer attached to the flag, the metal interposer having a metal die attach flag;
a semiconductor die attached to the metal die attach flag;
a plurality of wirebonds connected between the metal interposer and the leadframe;
a plurality of wirebonds connected between the semiconductor die and the metal interposer; and
an encapsulant formed over the die, the metal interposer, and a portion of the leadframe.

11. The semiconductor device of claim 10, wherein the metal interposer comprises a bus bar, wherein the plurality of wirebonds connected between the semiconductor die and the metal interposer are connected to the bus bar, and a single wire bond is connected between the bus bar and one lead of the plurality of leads of the leadframe.

12. The semiconductor device of claim 11, wherein the bus bar is used for routing a power supply voltage to the semiconductor device.

13. The semiconductor device of claim 10, wherein the metal interposer comprises a bus bar for enabling a high pin count semiconductor die to be wirebonded to a lower pin count leadframe.

14. The semiconductor device of claim 10, wherein both pluralities of wirebonds are formed using a wire comprising copper.

15. The semiconductor device of claim 10, wherein the leadframe and the metal interposer are both formed from a metal sheet comprising copper, and wherein the leadframe is characterized as a stamped leadframe and the metal interposer is characterized as a custom etched leadframe.

16. A semiconductor device comprising:
a leadframe having a plurality of leads and a flag;
a custom interposer attached to the flag, the custom interposer having a plurality of wirebond leads and a die attach flag, the plurality of wirebond leads and die attach flag formed from a same metal material as the leadframe;
a semiconductor die attached to the die attach flag of the custom interposer;
a plurality of wirebonds connected between the wirebond leads of the custom interposer and the leadframe;
a plurality of wirebonds connected between the semiconductor die and the wirebond leads of the custom interposer; and
an encapsulant formed over the die, the custom interposer, and a portion of the leadframe.

17. The semiconductor device of claim 16, wherein the leadframe and the custom interposer are both formed from a metal comprising copper.

18. The semiconductor device of claim 16, wherein the custom interposer comprises a bus bar for enabling a high pin count semiconductor die to be wirebonded to a lower pin count leadframe.

19. The semiconductor device of claim 16, wherein the semiconductor device is characterized as being one of a quad flat pack (QFP) package, small outline integrated circuit (SOIC) package, or quad flat no-lead (QFN) package.

20. The semiconductor device of claim 16, wherein the custom interposer is attached to the flag with a non-conductive die attach film.
